(19) United States
(12) Patent Application Publication
(10) Pub. No.: US 2016/0182043 A1
(43) Pub. Date: Jun. 23, 2016

(54) Context-Aware Electronic Apparatus, System and Methods thereof

(71) Applicant: Sivapathalingham Sivavakeesar, Milton Keynes (GB)

(72) Inventor: Sivapathalingham Sivavakeesar, Milton Keynes (GB)

(21) Appl. No.: 14/580,244

(22) Filed: Dec. 23, 2014

(51) Int. Cl. H03K 17/945; H03K 17/965

(52) U.S. Cl. CPC H03K 17/945; H03K 17/965

(57) ABSTRACT

Embodiments of the present invention provide a control system for power safe operations that selectively control the power supply to an electrical equipment. According to the present invention, motion sensor and/or human touch/presence sensor data indicative respectively of motion or safe-use of an electrical equipment may be received and processed. In addition, orientation/tilt sensor data indicative of current orientation/tilt of an electrical equipment may be received and processed. A determination may be made by comparing the current orientation against a threshold. A further determination may be made by comparing processed motion or human touch/presence sensor data to a threshold. Based on the determination, electrical supply to an electrical equipment may be suspended preferably after a warning. Warning can preferably be in the form of a flashing light or an audible sound and communicated to a user handheld device.

### TECHNICAL FIELD

The present invention relates to system, apparatus, circuit, arrangement and method pertaining to context-aware circuit breaker having capability to determine based on sensory information when to cut off power supply to an electrical equipment.

### BACKGROUND

Certain domestic electrical equipment needs continuous human presence for their safe use. In case such an electrical equipment is left unattended, it can cause health and safety issues while leading to wasting of electrical energy. However, it is very difficult for a person to stay close to an electrical equipment all the time and it is easy for a human to leave a turned on electrical equipment unattended. It is still a challenge for a system to correctly determine when it is safe to continuously supply electricity to an equipment that can be hazardous when left unattended.

At the moment, in order to detect continuous human presence, a human needs to press a button to ensure a continuous operation of an electrical equipment (e.g., lawn-mover). This can cause lots of inconvenience—first such a mechanism needs a human to exert a pressure in order to press a button. The second aspect is that power is unnecessary cut off when not intended. However, a correct balance has to be maintained to make sure that a power is not cut of unexpectedly; but at the same time energy is not wasted unnecessarily. It is a challenge to strike a right balance.

User context-awareness can be achieved by collecting user-related information. Sensors can preferably be used to learn context.

An accelerometer is an electromechanical device which is capable of measuring dynamic acceleration caused generally by movements or vibrations and static acceleration caused generally by gravity. Most accelerometers are Micro-Electro-Mechanical Sensors (MEMS).

An accelerometer or G-sensor can be realised using different ways. In the case of piezoelectric effect accelerometers, a microscopic crystal structures get stressed by accelerative forces and this causes a voltage to be generated. Alternatively in the case of capacitance-based accelerometer two microstructures are placed next to each other, with a certain capacitance between them. If an accelerative force moves one of the structures, the capacitance will change reflecting the movement or tilt.

Inclinometers (also known as gravitational or tilt sensors) measure an angle from the direction of Earth's centre of gravity. Typical example of such a sensor measuring continuous inclination is electrolytic tilt sensor. By containing an electrolytic fluid (electrolyte) partially filling a tube with three electrodes (one-axis sensors) or five electrodes (two-axis sensors) at its base, the electrical resistance between the centre electrode and the electrodes at the periphery will vary proportionally to the tilt angle.

Capacitive sensors are widely used for proximity sensing (personnel detection, light switching, and vehicle detection) or human touch. A capacitive touch sensor responds to close approach (but not force of touch) of a part of a human body, usually a fingertip. The capacitance between the device itself and the fingertip is sensed. They act on the principle of body capacitance.

Capacitive sensing operates on the principle of capacitive coupling that takes human body capacitance as input. Capacitive sensors detect anything that is conductive or has a dielectric different from that of air.

A gyroscope sensor measures an angular rate of rotation about one or more axes. Gyroscopes can measure complex motions accurately in free space, hence, making it a required motion sensor for tracking the position and rotation of a moving object. Unlike accelerometers and compasses, gyroscopes are not dependent on any external forces such as gravity or magnetic fields, and can therefore function fairly autonomously.

Piezo sensors are used to convert mechanical movements, such as force, vibration, acceleration or pressure, into electric signals. Piezoelectricity is the ability of some materials to generate an electric potential in response to applied mechanical stress. The piezoelectric effect is caused by the appearance of electric polarization in a material that strains under stress. Piezoelectricity is therefore a reversible effect: if a voltage is applied to a piezoelectric device, it will strain. The electrical response to mechanical stimulation is called the direct piezoelectric effect and the mechanical response to electrical simulation is called the converse piezoelectric effect.

A passive infrared sensor (PIR sensor) is used to sense movement of people, animals, or other objects. An individual PIR sensor detects changes in the amount of infrared radiation impinging upon it, which varies depending on the temperature and surface characteristics of the objects in front of the sensor. When an object, such as a human, passes in front of the background, such as a wall, the temperature at that point in the sensor's field of view will rise from room temperature to body temperature, and then back again. The sensor converts the resulting change in the incoming infrared radiation into a change in the output voltage, and this triggers the detection.

### SUMMARY OF INVENTION

According to the first embodiment of the present invention there is provided a context-aware circuit-breaker arrangement comprising:
i) Orientation determination means;
ii) Human presence sensing means;
iii) Control means
iv) An Electrical equipment

Characterised in that
a. the orientation determination means determining the orientation of the said electrical equipment and passing the outcome to the said control means;
b. the human presence sensing means sensing the human presence with respect to a physical location of the said electrical equipment and passing the outcome to the said control means;

Wherein the said control means cutting off the power supply to the said electrical equipment on determining that the orientation of the said electrical equipment exceeding a set threshold and no human presence is detected.

It is preferred that the said context-aware circuit-breaker arrangement, wherein the said orientation determination means determines orientation of the said electrical equipment with respect to gravity.

Preferably the said context-aware circuit-breaker arrangement, wherein the said human presence sensing means determines near-proximity or touch of a human.

It is preferred that the said context-aware circuit-breaker arrangement according to claim 1, wherein the said orientation determination means employing one or plurality of tilt sensors.

It is preferred that the said context-aware circuit-breaker arrangement, wherein the said orientation determination means employing one or plurality of accelerometers (G-sensors).

Preferably the said context-aware circuit-breaker arrangement, wherein the said human presence sensing means employing one or plurality of capacitive sensors.

It is preferred that the said context-aware circuit-breaker arrangement further comprising a user-warning means, wherein the said control means triggering a user warning before cutting off the power supply to the said electrical equipment.

Preferably the said context-aware circuit-breaker arrangement further comprising a user-warning means, wherein the user-warning means employing audible warning sound for a limited time.

It is preferred that the said context-aware circuit-breaker arrangement further comprising a user-warning means, wherein the user-warning means employing flashing lights for a limited time.

Preferably the said context-aware circuit-breaker arrangement further comprising a transceiver supporting a communication interface of first type for communicating with a mobile station, wherein the said control means alerting a user on a user's mobile station before cutting off the power supply to the said electrical equipment.

It is preferred that the said context-aware circuit-breaker arrangement further comprising a transceiver supporting a communication interface of first type for communicating with a mobile station, wherein the said control means alerting a user on a user's mobile station and getting a user input to decide on its operation.

Preferably the said context-aware circuit-breaker arrangement, wherein the said circuit-breaker taking external power supply through it.

It is preferred that the said context-aware circuit-breaker arrangement, wherein the said control means cutting off the power supply to the said electrical equipment on determining that the orientation of the said electrical equipment exceeding a set threshold and no human presence is detected within a time-period.

Preferably the said context-aware circuit-breaker arrangement characterised on that the said control means cutting off the power supply to the said electrical equipment on determining that the orientation of the said electrical equipment exceeding a set threshold and no human presence is detected within a time-period, wherein the said time-period is set by a user.

According to the second embodiment of the present invention there is provided a context-aware circuit-breaker device comprising:
i) Orientation determination means;
ii) Movement determination means;
iii) Control means;

Characterised in that the said circuit-breaker device lies between an external power supply and internal power input circuitry of an electrical equipment while
a. the orientation determination means determining the orientation of the said electrical equipment and passing the outcome to the said control means;
b. the movement determination means determining the movement of the said electrical equipment and passing the outcome to the said control means;

Wherein the said control means cutting off the power supply to the said electrical equipment on determining that the orientation of the said electrical equipment exceeding a set threshold and no movement of the said electrical equipment is detected.

It is preferred that the context-aware circuit-breaker device characterised in that the said orientation determination means determines orientation of the said electrical equipment with respect to gravity, wherein said orientation determination means employing one or plurality of accelerometers (G-sensors).

Preferably that the context-aware circuit-breaker device, wherein said movement determination means employing one or plurality of gyroscope sensors to determine any movement that is perpendicular to a gravitational force.

It is preferred that the context-aware circuit-breaker device, wherein said context-aware circuit-breaker device is an internal unit of the said electrical equipment.

Preferably that the context-aware circuit-breaker device, wherein said context-aware circuit-breaker device is an external unit of the said electrical equipment.

According to the third embodiment of the present invention there is provided a context-aware power-supplying method for monitoring a power supply operation to an electrical equipment characterised in that the said method
a. determining the orientation of the said electrical equipment;
b. determining the physical attachment to the said electrical equipment by a user;

Wherein the said method cutting off the power supply to the said electrical equipment on determining that the orientation of the said electrical equipment exceeding a set threshold and no physical user attachment to said electrical equipment is detected.

### DESCRIPTION OF THE DRAWINGS

Non-limited and non-exhaustive embodiments are described with reference to the following figures, wherein like reference numerals refer to like parts throughout the various views unless otherwise specified. For a better understanding of the present invention, reference will be made to the following detailed description of the invention, which is to be read in association with the accompanying drawings, wherein:

FIG. 1 exemplarily illustrates the basic building blocks making up a context-aware circuit-breaker device in its simplest form according to the first embodiment of the present invention.

FIG. 2 exemplarily illustrates the basic building blocks making up a context-aware circuit-breaker device in its simplest form according to the second embodiment of the present invention.

FIG. 3 is an exemplary illustration of a context-aware circuit-breaker arrangement in one of its enhanced forms it terms of its components according to the first embodiment of the present invention.

FIG. 4 is an exemplary illustration of a context-aware circuit-breaker arrangement in one of its enhanced forms it terms of its components according to the second embodiment of the present invention.

FIG. 5 exemplarily illustrates the working mechanism of a context-aware circuit-breaker arrangement according to the first embodiment of the present invention.

FIG. 6 exemplarily illustrates the working mechanism of a context-aware circuit-breaker arrangement according to the second embodiment of the present invention

FIG. 7-1-7-2 exemplarily illustrate the working mechanism of a context-aware circuit-breaker arrangement in a specific application scenario according to one embodiment of the present invention.

The figures are provided for ease of explanation of the basic proposals of the present invention only; the extensions of the figures with reference to number, position, relationship and dimensions of the parts to form the preferred embodiment will be explained or will be within the skill of the art after the following proposals/findings of the present invention have been read and understood.

### DESCRIPTION OF SPECIFIC EMBODIMENTS

A system, device, electronic circuit, method or arrangement for allowing context-aware power-supplying to an electrical equipment is provided. The main requirements in the proposed system, electronic circuit, device or arrangement are to enable at least:
i) capturing context regarding an electrical equipment:
   gathering the operational state of an electrical equipment; and,
   gathering the current orientation with respect to its safe orientation
ii) deciding whether to cut-off power supply or continue supplying electricity to ensure safe operation of a given electrical equipment while making an attempt to save electrical energy without wasting.

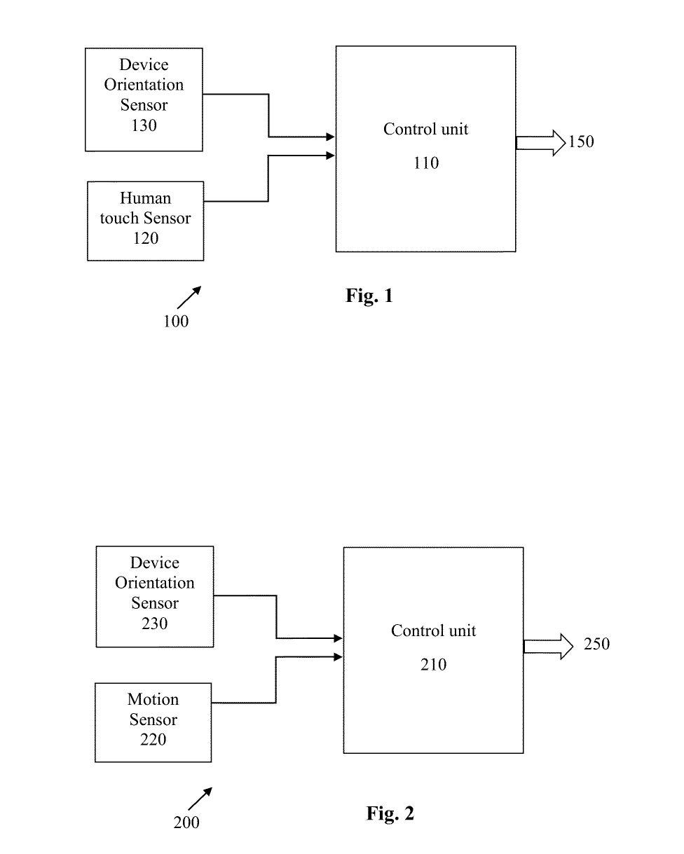

FIG. 1 exemplarily illustrates the basic building blocks making up a context-aware circuit-breaker device or circuit in its simplest form according to the first embodiment of the present invention. According to the first embodiment, the context-aware circuit-breaker device or circuit 100 in its elementary form consists of:
i) one or plurality of sensors 120 to determine human near-proximity or touch;
ii) one or plurality of sensors 130 to determine the orientation of an electrical equipment with respect to its safe position;
iii) a control element 110 to analyse the inputs from sensors 120 and 130 for the purpose of deciding whether to cut-off power or continue supplying power to a given electrical equipment.

The control unit 110 first compares the current orientation against the safest/default orientation of a given electrical equipment. The safest/default orientation of a given electrical equipment can be factory-configured and it can vary between different equipment. The safest/default orientation is defined as the orientation in which an electrical equipment can be left unattended (i.e., no continuous human/operator presence is required) when electricity is supplied. If the control unit 110 determines that the current orientation of an electrical equipment is unsafe for a continuous power supply, the control unit 110 will determine whether a human operator is currently operating the given electrical equipment.

According to the first embodiment of the present invention, if it is decided that the given electrical equipment is currently operated by a human, the control unit 110 will not cut off the power supply even when the given electrical equipment is not in its safest/default orientation as configured in priory (possibly at the time of manufacture). The control unit 110 will controls the operation of a given electrical equipment with its relevant output 150—the output can determine whether the power supply to a given electrical equipment needs to be cut off or not.

According to one arrangement, the control unit 110 is implemented with a microcontroller. Alternatively it can be implemented based on a microprocessor and associated components like RAM, ROM and the like as it will be appreciated by those persons skilled in the art. Alternatively, the control unit 110 can be a simple (preferably an electronic) on/off switch that takes input from sensors 120/130 and turn off the power if it is decided that the given electrical equipment is not in its safest/default orientation as configured in priory and no physical touch by a human/operator is detected.

According to the preferred arrangement of the first embodiment of the present invention, in order to decide whether a human is operating a given electrical equipment, sensor 120 can preferably be capacitive or human-touch sensors. Accordingly, the handle of an electrical equipment is equipped with a capacitive or human-touch-sensor and associated sensing electronic circuitry to instantaneously decide whether a user operates a given electrical equipment.

Alternatively, in order decide whether a human is operating a given electrical equipment, sensor 120 can preferably be piezo sensors. Accordingly, the handle of an electrical equipment contains piezoelectric elements and associated sensing electronic circuitry to instantaneously decide whether a user operates a given electrical equipment based on human grip/pressure exerted. This arrangement is useful when a human operator wears a hand-glove. Alternatively, sensor 120 can preferably make use a combination of capacitive or human-touch sensors and piezo sensors to decide whether a given equipment is operated by a human operator/user.

According to the preferred arrangement of the first embodiment of the present invention, in order to decide on the orientation of an electrical equipment, sensor 130 can preferably be an inclinometers or gravitational or tilt sensor having the ability to measure a tilting angle of a given electrical equipment from the direction of Earth's centre of gravity. By pre-configuring the safest orientation of an electrical equipment with respect to the direction of Earth's centre of gravity and comparing it against the current tilt measured, the control unit 110 can determine how safe a current orientation of an electrical equipment is.

Alternatively, in order to decide on the orientation of an electrical equipment, sensor 130 can preferably be accelerometer (G-sensors) having the ability to measure a tilting angle of a given electrical equipment from the direction of Earth's centre of gravity. Alternatively, sensor 130 may preferably employ a combination of inclinometers or gravitational or tilt sensor and accelerometer or similar means to determine an equipment's tilt with respect to the Earth's centre of gravity.

According to the preferred embodiment, the said circuit-breaker device 100 lies between an external power supply and internal power input circuitry of an electrical equipment. Also, the context-aware circuit-breaker device 100 can preferably be an internal unit of a given electrical equipment. Alternatively, the context-aware circuit-breaker device 100 can preferably be external to a given electrical equipment.

FIG. 2 exemplarily illustrates the basic building blocks making up a context-aware circuit-breaker device or circuit in its simplest form according to the second embodiment of the present invention. According to the second embodiment, the context-aware circuit-breaker device or circuit 200 in its elementary form consists of:
i) one or plurality of sensors 220 to determine whether an electrical equipment is in its operational state;
ii) one or plurality of sensors 230 to determine the orientation of an electrical equipment with respect to its safe position;
iii) a control element 210 to analyse the inputs from sensors 220 and 230 for the purpose of deciding whether to cut-off power or continue supplying power to a given electrical equipment.

The control unit 210 first compares the current orientation against the safest/default orientation of a given electrical equipment. The safest/default orientation of a given electrical equipment can be factory-configured and it can vary between different equipment. If the control unit 210 determines that the current orientation of an electrical equipment is unsafe for a continuous power supply, the control unit 210 will determine whether a human operator is currently operating the given electrical equipment.

According to the second embodiment of the present invention, if it is decided that the given electrical equipment is currently operated by a human, the control unit 210 will not cut off the power supply even when the given electrical equipment is not in its safest/default orientation as configured in priory (possibly at the time of manufacture). The control unit 210 will controls the operation of a given electrical equipment with its relevant output 250.

According to one arrangement, the control unit 210 is implemented with a microcontroller. Alternatively it can be implemented based on a microprocessor and associated components like RAM, ROM and the like as it will be appreciated by those persons skilled in the art. Alternatively, the control unit 210 can be a simple (preferably an electronic) on/off switch that takes input from sensors 220/230 and turn off the power if it is decided that the given electrical equipment is not in its safest/default orientation as configured in priory and not operated currently by any human operator/user.

According to the preferred arrangement of the second embodiment of the present invention, in order to decide whether a human is operating a given electrical equipment, sensor 220 can preferably be movement or motion sensors. This is useful when an electrical equipment makes physical movement when used by a human. For this purpose, sensor 220 can be made up of one or plurality of accelerometers (G-sensors) or gyroscope sensors or combination of both.

According to one aspect of the preferred embodiment, the intended movement take place in the horizontal plane (i.e., perpendicular to a gravitational force)—hence determining the horizontal movement is required.

According to the preferred arrangement of the second embodiment of the present invention, in order to decide on the orientation of an electrical equipment, sensor 230 can preferably be built based on accelerometer (G-sensor) or gyroscope sensing.

Alternatively, in order to decide on the orientation of an electrical equipment, sensor 230 can preferably be inclinometers or gravitational or tilt sensor having the ability to measure a tilting angle of a given electrical equipment from the direction of Earth's centre of gravity. Alternatively, sensor 230 may preferably employ a combination of inclinometers or gravitational or tilt sensor and accelerometer (G-sensor) or gyroscope or similar means to determine an equipment's tilt with respect to the Earth's centre of gravity.

By pre-configuring the safest orientation of an electrical equipment with respect to the direction of Earth's centre of gravity and comparing it against the current tilt measured, the control unit 210 can determine how safe a current orientation of an electrical equipment is. According to the preferred embodiment, the said circuit-breaker device 200 lies between an external power supply and internal power input circuitry of an electrical equipment. Also, the context-aware circuit-breaker device 200 can preferably be an internal unit of a given electrical equipment. Alternatively, the context-aware circuit-breaker device 200 can preferably be external to a given electrical equipment.

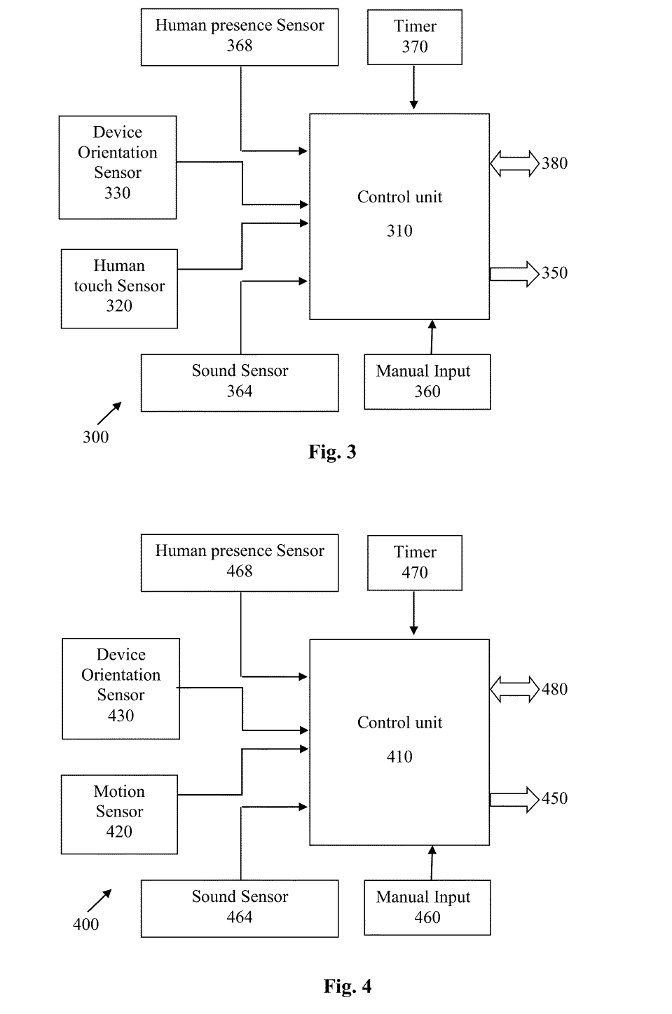

FIG. 3 is an exemplary illustration of a context-aware circuit-breaker arrangement in one of its enhanced forms it terms of its components according to the first embodiment of the present invention. In terms of functionalities, 320, 330 and 350 are similar to 120, 130 and 150 respectively.

When an electrical equipment is in its safe orientation as decided by the control unit 310 based on input from device orientation sensor 330 and the given electrical equipment is turned on by a user, the control unit 310 will continuously supply electricity as long as human presence detector 368 or human touch sensor detects a human presence. If, on the other hand, human presence is not detected within a given time period of first type, the control unit 310 will turned the power off.

According to the preferred arrangement of the first embodiment, human presence detector 368 can preferably be a Passive Infra-Red sensor. Alternatively, human presence can be detected with a sound detector 364. The time period of first type can be user set using a timer unit 370 or can take a default value.

When the control unit 310 decides to turn the power off to a given electrical equipment, it can preferably draw the attention of a user by triggering an audible alarm or flashing light for a preferred time-period of second type or both. In addition, the control unit 310 can alert a user of its intention on a user's handheld device (e.g., mobile phone, tablet, laptop and the like) via a communication interface of first type 380. The communication interface of first type 380 can preferably be implemented based on any short-range radio technology such as IEEE 802.11, Bluetooth, Zigbee, Near Field Communication (NFC), DECT and the like. A user can preferably control the operation of context-aware circuit-breaker device or circuit 300 using a user's handheld device via a communication interface of first type 380. For this purpose the context-aware circuit-breaker 300 can preferably possess a transceiver to support the communication interface of first type 380.

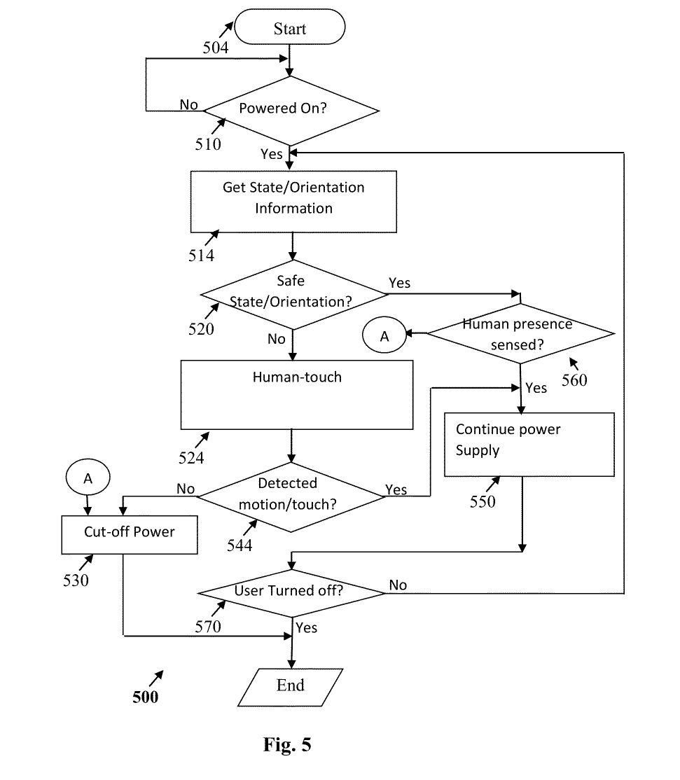

FIG. 4 is an exemplary illustration of a context-aware circuit-breaker arrangement in one of its enhanced forms it terms of its components according to the second embodiment of the present invention. In terms of functionalities, 420, 430 and 450 are similar to 220, 230 and 250 respectively.

When an electrical equipment is in its safe orientation as decided by the control unit 410 based on input from device orientation sensor 430 and the given electrical equipment is turned on by a user, the control unit 410 will continuously supply electricity as long as human presence detector 468 detects a human presence. If, on the other hand, human presence is not detected within a given time period of first type, the control unit 410 will turned the power off. According to the preferred arrangement of the first embodiment, human presence detector 468 can preferably be a Passive Infra-Red sensor. Alternatively, human presence can be detected with a sound detector 464. The time period of first type or time period of second type can be user settable using a timer unit 470 or can take a default value.

When the control unit 410 decides to turn the power off to a given electrical equipment, it can preferably draw the attention of a user by triggering an audible alarm or flashing light for a preferred time-period of second type or both. In addition, the control unit 410 can alert a user of its intention on a user's handheld device (e.g., mobile phone, tablet, laptop and the like) via a communication interface of first type 480.

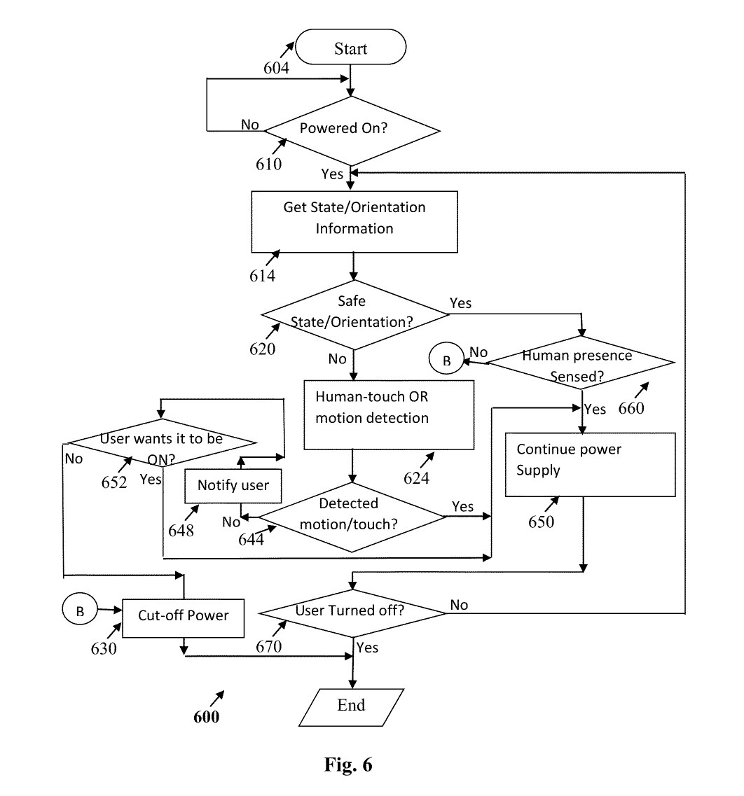

FIG. 5 exemplarily illustrate the operation of context-aware circuit-breaker device or circuit 100/300 according to the first embodiment of the present invention. At the decision-making step 510, the control unit 110/310 checks whether the power supply to a given electrical equipment is turned on by a user. If power supply is turned on, the control unit 110/310 will get the device orientation sensor 130/330 to report the current orientation of a given electrical equipment as indicated by processing step 514. On getting the current orientation, the control unit 110/310 compares the input value with the pre-configured default/safe orientation to decide on whether a given electrical equipment takes its safe orientation as indicated in the decision-making step 520. If a given electrical equipment is not in its safe orientation as decided in step 520, the control unit 110/310 checks with sensors 130/330 to find out in step 524 whether any human currently operates an electrical equipment. If it is decided in step 544 that no user currently operates a given electrical equipment, the control unit 110/310 will cut off the electrical supply to that electrical equipment.

On the other hand, if it is decided in step 544 that a user is currently operating an electrical equipment, the control unit 110/310 will make sure that power is continuously supplied to a given electrical equipment as indicated in step 550 unless it is decided at step 570 that a user would like to turn off an electrical equipment. In the decision making step 520, if it is decided that a given electrical equipment takes a safe orientation, it will be further checked in 560 whether any human presence is sensed—if it is the case the control unit 110/310 will continue the power supply as indicated in step 550. In case, no human presence is sensed, the control unit will cut off power as indicated by step 530.

FIG. 6 exemplarily illustrate the operation of context-aware circuit-breaker device or circuit 200/400 according to the second embodiment of the present invention. At the decision-making step 610, the control unit 210/410 checks whether the power supply to a given electrical equipment is turned on by a user. If power supply is turned on, the control unit 210/410 will get the device orientation sensor 230/430 to report the current orientation of a given electrical equipment as indicated by processing step 614. On getting the current orientation, the control unit 210/410 compares the input value with the pre-configured default/safe orientation to decide on whether a given electrical equipment takes its safe orientation as indicated in the decision-making step 620. If a given electrical equipment is not in its safe orientation as decided in step 620, the control unit 210/410 checks with sensors 230/430 to find out in step 624 whether any human currently operates an electrical equipment. If it is decided in step 644 that no user currently operates a given electrical equipment, the control unit 210/410 will first notify a user regarding its intended action of cutting off the electrical supply to that electrical equipment as indicated in step 648. On receiving the notification, if a user would like the power to be continuously supplied to a given electrical equipment as checked in 652, the control unit 210/410 will make sure that the power supply is not interrupted as indicated by step 650. Necessary user inputs are made in this connection via the communication interface of first type 480.

If, on the other hand, no user wants a given electrical equipment to be powered-on as checked in step 652, the control unit 210/410 will cut off the power as indicated by step 630. On the other hand, if it is decided in step 644 that a user is currently operating an electrical equipment based on input from movement sensors 220/420, the control unit 210/410 will make sure that power is continuously supplied to a given electrical equipment as indicated in step 650 unless it is decided at step 670 that a user would like to turn off an electrical equipment.

In the decision making step 620, if it is decided that a given electrical equipment takes a safe orientation, it will be further checked in 660 whether any human presence is sensed—if it is the case the control unit 210/410 will continue the power supply as indicated by step 650. In case, no human presence is sensed, the control unit 210/410 will cut off power as indicated by step 630.

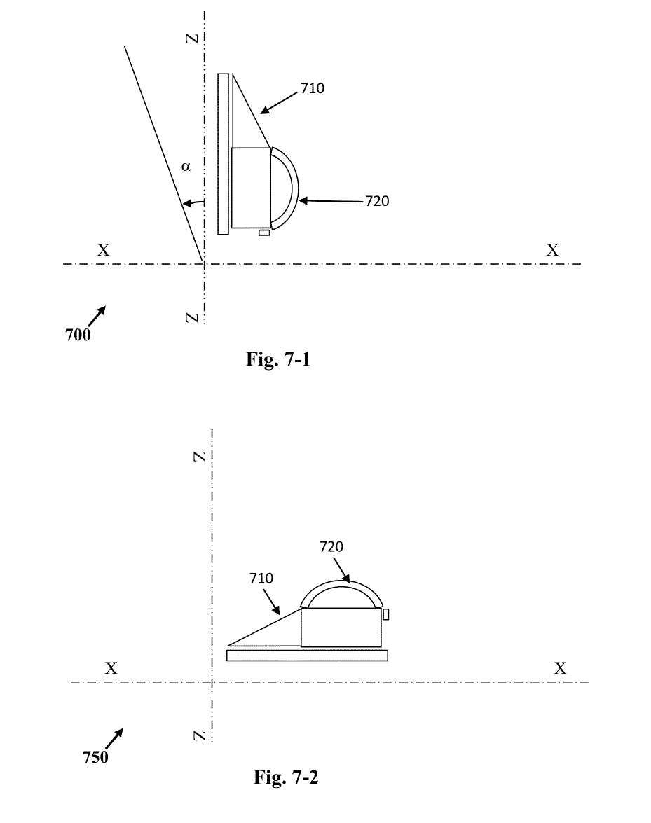

FIG. 7-1-7-2 exemplarily illustrate the working mechanism of a context-aware circuit-breaker device or circuit 100/200/300/400 in a specific application scenario according to one embodiment of the present invention. In this case an electric iron is exemplarily considered as an electrical equipment which context-aware circuit-breaker is supposed to work with. The safe orientation of this electric iron is shown by a line Z-Z (i.e., a vertical line which is parallel to the Earth's gravitational force). If the considered electric iron takes any tilt as indicated by a tilting angle (i.e., α>0) preferably with respect to the Earth's centre of gravity, it is considered to be taking an unsafe orientation. In this case, the control unit of the context-aware circuit-breaker device or circuit that operates in conjunction with this electric iron will cut off the power unless the control unit 110/210/310/410 decides that a user is currently operating a given iron. FIG. 7-2 shows an exemplary unsafe orientation where (i.e., α=90 degrees) the orientation of a given electrical equipment is perpendicular to the Earth's centre of gravity.

In case the context-aware circuit-breaker device or circuit 100/200/300/400 is internally built inside an electrical equipment, it can preferably be housed such that it is not impacted due to the normal operation of an electrical equipment due to excessive heat, vibration, pressure and the like. For example, in the case of an electric iron, the context-aware circuit-breaker device or circuit 100/200/300/400 can preferably be housed inside the handle.

All described embodiments of the present invention are readily applicable to ensure safe operation of such domestic electrical equipment as vacuum cleaner, carpet cleaner, floor polisher and kettle. However similar principles can be applied to other electrical equipment within the purview of the appended claims without departing from the spirit and intended scope of the invention.

The context-aware circuit-breaker device or circuit 100/200/300/400 can be implemented through software and/or hardware means. In a software-based system, the functional units described hereinabove may be implemented on a computer system (commonly, a server, personal computer or mobile computing platform) executing program instructions corresponding to the functional blocks and methods listed above. The program instructions themselves may be stored in a storage device, such as an electrical, optical or magnetic storage medium, and executed by a processor of the computer system. In a hardware-based system, the functional blocks illustrated above may be provided in dedicated functional units of processing hardware, for example, digital signal processors, application specific integrated circuits, field programmable logic arrays and the like. The processing hardware may include state machines that perform the methods described in the foregoing discussion. The principles of the present invention also find application in hybrid systems of mixed hardware and software designs.

Several embodiments of the invention are specifically illustrated and/or described herein. However, it will be appreciated that modifications and variations of the invention are covered by the above teachings and within the purview of the appended claims without departing from the spirit and intended scope of the invention.

1. A context-aware circuit-breaker arrangement comprising:
i) Orientation determination means;
ii) Human presence sensing means;
iii) Control means
iv) An Electrical equipment
Characterised in that
a. the orientation determination means determining the orientation of the said electrical equipment and passing the outcome to the said control means;
b. the human presence sensing means sensing the human presence with respect to a physical location of the said electrical equipment and passing the outcome to the said control means;
Wherein the said control means cutting off the power supply to the said electrical equipment on determining that the orientation of the said electrical equipment exceeding a set threshold and no human presence is detected.

2. The context-aware circuit-breaker arrangement according to claim 1, wherein the said orientation determination means determines orientation of the said electrical equipment with respect to gravity.

3. The context-aware circuit-breaker arrangement according to claim 1, wherein the said human presence sensing means determines near-proximity or touch of a human.

4. The context-aware circuit-breaker arrangement according to claim 1, wherein the said orientation determination means employing one or plurality of tilt sensors.

5. The context-aware circuit-breaker arrangement according to claim 1, wherein the said orientation determination means employing one or plurality of accelerometers (G-sensors).

6. The context-aware circuit-breaker arrangement according to claim 1, wherein the said human presence sensing means employing one or plurality of capacitive sensors.

7. The context-aware circuit-breaker arrangement according to claim 1 further comprising a user-warning means, wherein the said control means triggering a user warning before cutting off the power supply to the said electrical equipment.

8. The context-aware circuit-breaker arrangement according to claim 1 further comprising a user-warning means, wherein the user-warning means employing audible warning sound for a limited time.

9. The context-aware circuit-breaker arrangement according to claim 1 further comprising a user-warning means, wherein the user-warning means employing flashing lights for a limited time.

10. The context-aware circuit-breaker arrangement according to claim 1, further comprising a transceiver supporting a communication interface of first type for communicating with a mobile station, wherein the said control means alerting a user on a user's mobile station before cutting off the power supply to the said electrical equipment.

11. The context-aware circuit-breaker arrangement according to claim 1, further comprising a transceiver supporting a communication interface of first type for communicating with a mobile station, wherein the said control means alerting a user on a user's mobile station and getting a user input to decide on its operation.

12. The context-aware circuit-breaker arrangement according to claim 1, wherein the said circuit-breaker taking external power supply through it.

13. The context-aware circuit-breaker arrangement according to claim 1, wherein the said control means cutting off the power supply to the said electrical equipment on determining that the orientation of the said electrical equipment exceeding a set threshold and no human presence is detected within a time-period.

14. The context-aware circuit-breaker arrangement according to claim 1 characterised on that the said control means cutting off the power supply to the said electrical equipment on determining that the orientation of the said electrical equipment exceeding a set threshold and no human presence is detected within a time-period, wherein the said time-period is set by a user.

15. A context-aware circuit-breaker device comprising:
i) Orientation determination means;
ii) Movement determination means;
iii) Control means;
Characterised in that the said circuit-breaker device lies between an external power supply and internal power input circuitry of an electrical equipment while
a. the orientation determination means determining the orientation of the said electrical equipment and passing the outcome to the said control means;
b. the movement determination means determining the movement of the said electrical equipment and passing the outcome to the said control means;
Wherein the said control means cutting off the power supply to the said electrical equipment on determining that the orientation of the said electrical equipment exceeding a set threshold and no movement of the said electrical equipment is detected.

16. The context-aware circuit-breaker device according to claim 15 characterised in that the said orientation determination means determines orientation of the said electrical equipment with respect to gravity, wherein said orientation determination means employing one or plurality of accelerometers (G-sensors).

17. The context-aware circuit-breaker device according to claim 15, wherein said movement determination means employing one or plurality of gyroscope sensors to determine any movement that is perpendicular to a gravitational force.

18. The context-aware circuit-breaker device according to claim 15, wherein said context-aware circuit-breaker device is an internal unit of the said electrical equipment.

19. The context-aware circuit-breaker device according to claim 15, wherein said context-aware circuit-breaker device is an external unit of the said electrical equipment.

20. A context-aware power-supplying method for monitoring a power supply operation to an electrical equipment involving the determination of:
a. the orientation of the said electrical equipment;
b. the physical attachment to the said electrical equipment by a user;
Wherein the said method cutting off the power supply to the said electrical equipment on determining that the orientation of the said electrical equipment exceeding a set threshold and no physical user attachment to said electrical equipment is detected.
